(19) United States
(12) Patent Application Publication
(10) Pub. No.: US 2010/0109074 A1
(43) Pub. Date: May 6, 2010

(54) Gate structure, semiconductor memory device having the gate structure and methods of fabricating the same

(76) Inventors: Kwang-Soo Seol, Suwon-si (KR); Byung-Kl Kim, Gunpo-si (KR); Eun-Kyung Lee, Suwon-si (KR); Yo-Sep Min, Yongin-si (KR); Kyung-Sang Cho, Gwacheon-si (KR); Jae-Ho Lee, Yongin-si (KR); Jae-Young Choi, Suwon-si (KR)

Correspondence Address: HARNESS, DICKEY & PIERCE, P.L.C., P.O. BOX 8910, RESTON, VA, 20195, US

(21) Appl. No.: 12/654,029

(22) Filed: Dec. 8, 2009

Related U.S. Application Data
(63) Continuation of application No. 11/594,966, filed on Nov. 9, 2006.

(30) Foreign Application Priority Data
Nov. 11, 2005 (KR) 10-2005-0108126

(51) Int. Cl. H01L 29/792

(52) U.S. Cl. 257/325; 257/E29.309

(57) ABSTRACT

A gate structure using nanodots as a trap site, a semiconductor device having the gate structure and methods of fabricating the same are provided. The gate structure may include a tunneling layer, a plurality of nanodots on the tunneling layer, and a control insulating layer including a high-k dielectric layer on the tunneling layer and the nanodots. A semiconductor memory device may further include a semiconductor substrate, the gate structure according to example embodiments on the semiconductor substrate and a first impurity region and a second impurity region in the semiconductor substrate, wherein the gate structure is in contact with the first and second impurity regions.

### PRIORITY STATEMENT

This application is a continuation application of U.S. Ser. No. 11/594,966, filed Nov. 9, 2006, which claims priority under 35 USC §119 to Korean Patent Application No. 10-2005-0108126, filed on Nov. 11, 2005, in the Korean Intellectual Property Office (KIPO), the entire contents of which are incorporated herein by reference.

### BACKGROUND

1. Field

Example embodiments relate to a gate structure, a semiconductor memory device having the gate structure and methods of fabricating the same. Other example embodiments relate to a gate structure using nanodots as a trap site and improving semiconductor device characteristics by forming a high-k dielectric layer as a control insulating layer on a tunneling layer and nanodots, a semiconductor device having the gate structure and methods of fabricating the same.

2. Description of the Related Art

Performance of a semiconductor memory device has developed in order to increase an information storage capacity and speeds of recording and erasing the information. A semiconductor memory array structure may include a number of memory unit cells connected in circuits, and an information storage capacity of a semiconductor memory device may be proportional to an integration density of the device.

Semiconductor memory devices have been introduced with a shape and an operation principle. For example, a structure of a semiconductor memory device, in which a giant magneto-resistance (GMR) and/or tunneling magneto-resistance (TMR) structure is formed on a transistor, has been introduced. Recently, a new structure of a non-volatile semiconductor memory device, for example, a phase-change random access memory (PRAM) using phase transition material characteristics, and a SONOS having a tunneling layer, a charge storage layer, and a blocking layer has been introduced.

FIG. 1A is a diagram illustrating a typical structure of a conventional semiconductor memory device having nanodots as a trap site. Referring to FIG. 1, a first impurity region 11a and a second impurity region 11b, which are doped with dopants, may be formed in a semiconductor substrate 10. A channel region may be disposed in the semiconductor substrate 10 between the first impurity region 11a and the second impurity region 11b. A gate structure may be formed on the semiconductor substrate 10 contacting the first impurity region 11a and the second impurity region 11b. The gate structure may include a tunneling layer 12, a charge storage layer including nanodots 13, a blocking layer 14, and a gate electrode layer 15, which are sequentially stacked.

The tunneling layer 12 may contact the first impurity region 11a and the second impurity region 11b and the nanodots 13 may function as a trap site storing charges passing through the tunneling layer 12. In the structure of the semiconductor memory device shown in FIG. 1A, information may be recorded by a Fowler-Nordheim tunneling method when electrons passing through the tunneling layer 12 on the substrate 10 of the channel region between the first impurity region 11a and the second impurity region 11b may be trapped in the nanodots 13 as a trap site of the control insulating layer 14. FIG. 1B illustrates a configuration of a quantum well of the semiconductor memory device shown in FIG. 1A. A theory formula of a Fowler-Nordheim tunneling current passing through the tunneling layer 12 may be represented as follows.

J_{F-N}∝E²exp(−φ/E) [Formula 1]

Herein, J_{F-N} represents a current junction, E represents an electric field, and φ represents an injection barrier. In the semiconductor memory device using the nanodots 13 as a trap site shown in FIG. 1A, the tunneling layer 12 and the control insulating layer 14 may all be composed of a same material, for example, SiO₂. Because the tunneling layer 12 and the control insulating layer 14 have the same permittivity (ε), they also may have the same electric field (E). Because current junction values (J_{F-N}) of the tunneling layer 12 and the control insulating layer 14 are similar, and electrons passing through the tunneling layer 12 go out through the control gate layer 14, there may occur a program where the program efficiency decreases.

### SUMMARY

Example embodiments provide a gate structure including nanodots for improving information storage characteristics of the memory device by improving the structure of a control insulating layer of the memory device, a semiconductor device having the gate structure and methods of fabricating the same.

According to example embodiments, a gate structure may include a tunneling layer, a plurality of nanodots on the tunneling layer and a control insulating layer including a high-k dielectric layer on the tunneling layer and the nanodots. According to example embodiments, a semiconductor device may include a semiconductor substrate, a first impurity region and a second impurity region formed in the semiconductor substrate and a gate structure according to example embodiments formed on the semiconductor substrate and in contact with the first and second impurity regions.

The control gate layer may be composed of a material having a higher permittivity than that of the tunneling layer. The control insulating layer may include at least one insulating layer and the high-k dielectric layer formed on the at least one insulating layer. The control insulating layer may include the high-k dielectric layer and at least one insulating layer formed on the high-k dielectric layer. The high-k dielectric layer may include at least one material of high-k dielectric materials selected from Si₃N₄, Al₂O₃, HfO₂, Ta₂O₅, ZrO₂, HfSiO₄, and ZrSiO₄. The plurality of nanodots may be one of metal materials having a higher work function (e.g., Ni, Cu, Pd, Au, Ag, Fe, Co, Mn, Cr, V, Mo, Nb and/or Ru). A gate electrode layer may be formed on the high-k dielectric layer or the at least one insulating layer. The at least one insulating layer may include at least two insulating layers composed of the same material. The gate electrode layer may be composed of Ru, TaN metal or a silicide material.

According to example embodiments, a method of fabricating a gate electrode may include forming a tunneling layer on a semiconductor substrate, forming a plurality of nanodots on the tunneling layer by coating the tunneling layer with a dispersion solvent having dispersed nanodots and forming a control insulating layer including a high-k dielectric layer on the tunneling layer and the nanodots. According to example embodiments, a method of fabricating a semiconductor memory device may include forming the gate structure according to example embodiments on the semiconductor substrate and forming a first impurity region and a second impurity region in the semiconductor substrate, wherein the gate structure is in contact with the first and second impurity regions.

Forming the control insulating layer may include forming at least one insulating layer on the tunneling layer and the nanodots and forming the high-k dielectric layer composed of a material having a higher permittivity than that of the tunneling layer, on the at least one insulating layer. The insulating layer may be formed by performing an LPCVD process under an ambient of SiH₄ and/or O₂.

### BRIEF DESCRIPTION OF THE DRAWINGS

Example embodiments will be more clearly understood from the following detailed description taken in conjunction with the accompanying drawings. FIGS. 1A-6B represent non-limiting, example embodiments as described herein.

FIG. 1A is a diagram illustrating a typical structure of a conventional semiconductor memory device having nanodots as a trap site;

FIG. 1B is a diagram illustrating a quantum well structure of the nanodot semiconductor memory device of FIG. 1A;

FIG. 2 is a diagram illustrating a structure of a semiconductor memory device using metal nanodots as a trap site according to example embodiments;

FIGS. 3A-3C are diagrams illustrating a structure of a semiconductor memory device using metal nanodots as a trap site according to example embodiments;

FIGS. 4A-4F are diagrams illustrating a method of fabricating a semiconductor memory device using metal nanodots as a trap site according to example embodiments;

FIG. 5 is a photograph by an electron microscope illustrating a section of a semiconductor memory device using metal nanodots as a trap site according to example embodiments;

FIG. 6A is a graph illustrating programming-erasing characteristics of a semiconductor memory device using metal nanodots as a trap site according to example embodiments; and

FIG. 6B is a graph illustrating programming-erasing characteristics of a conventional semiconductor memory device including nanodots.

### DETAILED DESCRIPTION OF EXAMPLE EMBODIMENTS

Hereinafter, a semiconductor memory device including nanodots according to example embodiments will be explained in detail with reference to the accompanying drawings. In the drawings, the thicknesses and shapes of layers are exaggerated for description of exemplary embodiments. Like reference numbers refer to like elements throughout the specification.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

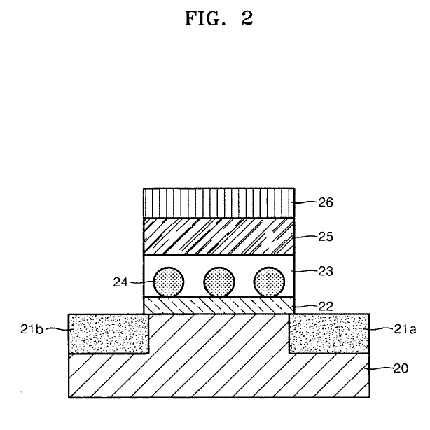

FIG. 2 is a diagram illustrating a structure of a semiconductor memory device including metal nanodots according to example embodiments. Referring to FIG. 2, a semiconductor substrate 20 having a first impurity region 21a doped with dopants, and a second impurity region 21b may be provided. A gate structure may be formed on the semiconductor substrate 20 between the first impurity region 21a and the second impurity region 21b. Example embodiments may be characterized in that a control insulating layer may be composed of a material having a higher permittivity than that of a tunneling layer 22. When the tunneling layer is composed of SiO₂, the control insulating layer may be composed of a high-k material having a higher permittivity than that of the tunneling layer 22, for example, Si₃N₄, Al₂O₃, HfO₂, Ta₂O₅ and/or ZrO₂.

In the semiconductor memory device including nanodots according to example embodiments, the control insulating layer may be formed of a single-layered and/or a multi-layered structure. When the control insulating layer is formed of a single layer, it may be formed to include a material having a higher permittivity than that of the tunneling layer 22 as described above. When the control insulating layer is formed of a multi-layered structure, it may be formed to include a material layer having a higher permittivity than that of the tunneling layer 22. FIG. 2 illustrates a control insulating layer which may include a first control insulating layer 23 composed of a typical insulating material, and a high-k dielectric layer 25 having a higher permittivity than that of the tunneling layer 22 and including nanodots 24. When the control insulating layer is formed of a single layer, the first control insulating layer 23 and the high-k dielectric layer 25 may be composed of the same material. A gate electrode layer 26 may be composed of Ru, TaN metal and/or a silicide material (e.g., NiSi), which may be used as a typical gate electrode of a semiconductor memory device.

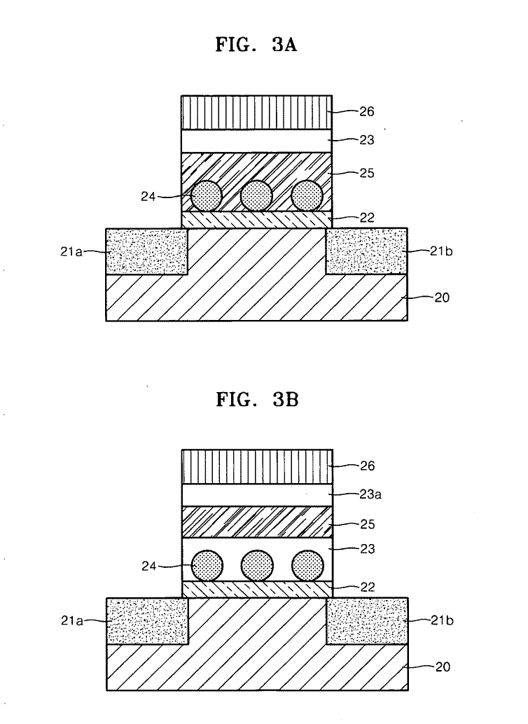

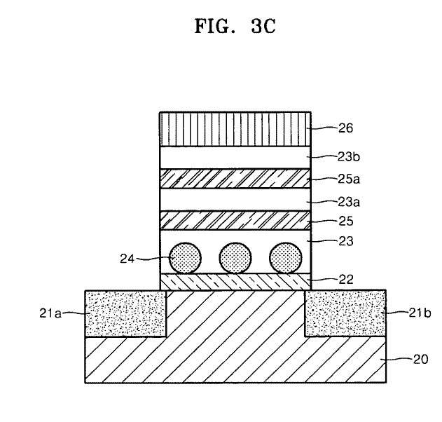

FIGS. 3A-3C are diagrams illustrating structures of a semiconductor memory device, in which a structure of a control insulating layer may be changed. Referring to FIG. 3A, a tunneling layer 22 may be formed on a semiconductor substrate 20 having a first impurity region 21a and a second impurity region 21b formed therein, and a high-k dielectric layer 25 may be formed on the tunneling layer 22. The high-k dielectric layer 25 may be composed of a material having a higher permittivity than that of the tunneling layer 22, and may include nanodots 24. An insulating layer 23 may be formed on the high-k dielectric layer 25. A gate electrode layer 26 may be formed on the insulating layer.

Referring to FIG. 3B, a tunneling layer 22 may be formed on a semiconductor substrate 20 having a first impurity region 21a and a second impurity region 21b formed therein, and on the tunneling layer 22, there may be sequentially formed an insulating layer 23 including nanodots 24, a high-k dielectric layer 25 composed of a material having a higher permittivity than that of the tunneling layer 22 and a second insulating layer 23a. The insulating layer 23 and the second insulating layer 23a may be composed of the same material, for example, SiO₂.

Referring to FIG. 3C, a tunneling layer 22 may be formed on a semiconductor substrate 20 having a first impurity region 21a and a second impurity region 21b formed therein, and on the tunneling layer 22, there may be sequentially formed an insulating layer 23 including nanodots 24, a high-k dielectric layer 25 composed of a material having a higher permittivity than that of the tunneling layer 22, a second insulating layer 23a, a second high-k dielectric layer 25, and a third insulating layer 23b. The insulating layer 23, the second insulating layer 23a, and the third insulating layer 23b may be all composed of an insulating material, for example, SiO₂. The high-k dielectric layer 25 and the second high-k dielectric layer 25 may be composed of a material having a higher permittivity than that of the tunneling layer 22.

When the control insulating layer of example embodiments is formed to include the high-k dielectric layer 23 having a higher permittivity than that of the tunneling layer 22, example embodiments provide an advantage as follows. For example, in the semiconductor memory device, in which the tunneling layer 22 is composed of SiO₂, Ni nanodots may be formed on the tunneling layer 22 and the high-k dielectric layer 25 may be formed on the Ni nanodots by depositing Al₂O₃, because the high-k dielectric layer 25 may have a higher permittivity (ε) and an electric field (E) may be relatively focused on the tunneling layer 22. Because the tunneling layer 22 has a higher current junction value (J_{F-N}) than that of the high-k dielectric layer 25, example embodiments provide a higher programming effectiveness. Because the high-k dielectric layer and the insulating layer are formed, the phenomenon of charges being back-tunneled from a gate electrode layer 26 and programmed may be reduced or prevented.

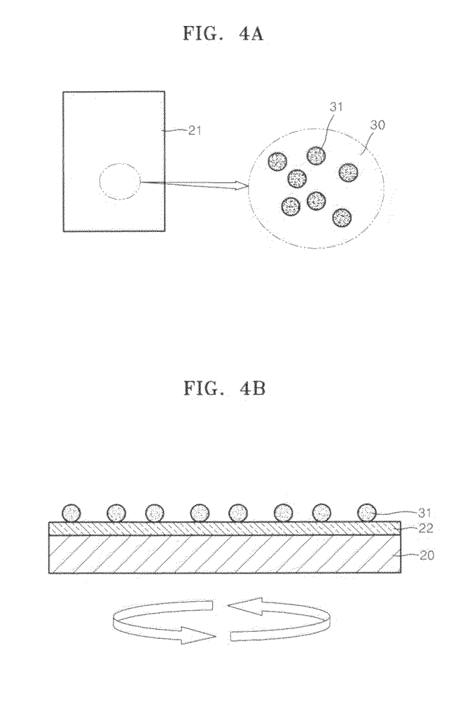

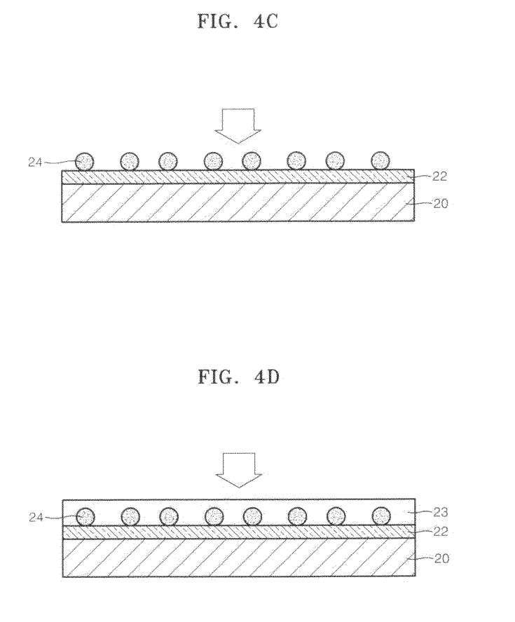

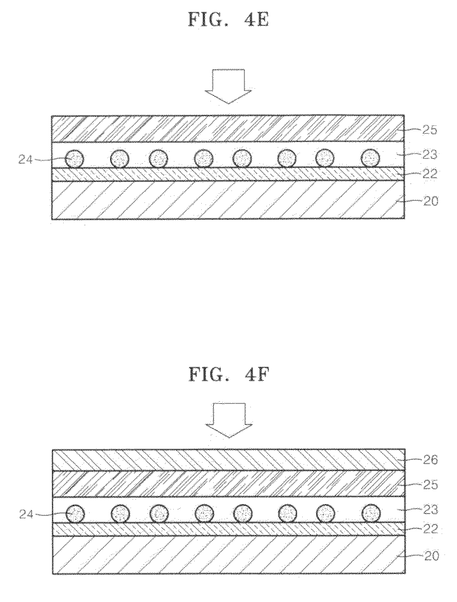

Hereinafter, a method of fabricating a semiconductor memory device including nanodots according to example embodiments will be explained in detail with reference to FIGS. 4A-4E. Referring to FIG. 4A, a dispersion solvent 30 having dispersed nano particles 31 may be prepared. The nanodots 31 may be composed of a conductive material capable of trapping charges, and may be composed of a metal material having a relatively high work function (e.g., Ni, Cu, Pd, Au, Ag, Fe, Co, Mn, Cr, V, Mo, Nb and/or Ru). Referring to FIG. 4B, SiO₂ may be deposited on the semiconductor substrate 20 (e.g., Si and/or SiO₂) using a typical semiconductor fabrication method, thereby forming a tunneling layer 22. When nano particles 31 are deposited on the tunneling layer 22 and dried, nanodots 24 (see FIG. 4C) may be formed on the tunneling layer 22.

Referring to FIG. 4C, residues may be removed by performing an oxygen plasma process and/or a thermal treatment process. As shown in FIG. 4D, an insulating layer 23 may be formed on the tunneling layer 22 and the nanodots 24 by supplying SiH₄ and oxygen and performing an LPCVD process at a temperature of about 450° C. Referring to FIG. 4E, a high-k dielectric layer 25 may be formed on the insulating layer 23 by performing an ALD process at a temperature of about 350° C. The high-k dielectric layer 25 may be composed of a material having a higher permittivity than that of the tunneling layer 22, for example, the tunneling layer 22 may be composed of SiO₂, and the high-k dielectric layer 25 may be composed of a high-k dielectric material (e.g., Si₃N₄, Al₂O₃, HfO₂, Ta₂O₅, ZrO₂, HfSiO₄ and/or ZrSiO₄).

Referring to FIG. 4F, a conductive material (e.g., metal and/or silicide) may be formed on the high-k dielectric layer 25 by performing a sputtering process and/or an E-beam evaporation process, thereby forming a gate electrode layer 26. The processes of forming the gate structure on the semiconductor substrate 20 and forming a first impurity region 21a and a second impurity region 21b by etching both side portions of the semiconductor substrate 20 and implanting impurities may be performed using typical semiconductor processing technology.

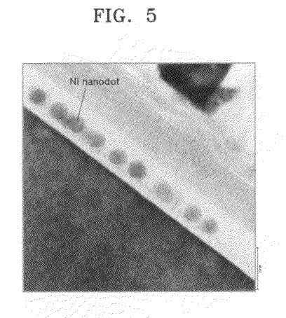

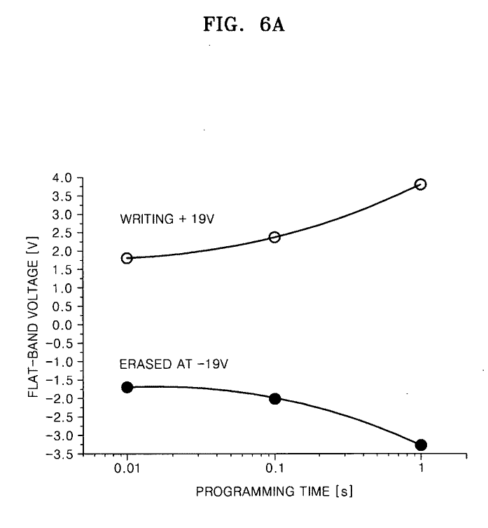

FIG. 5 illustrates a transmission electron microscopy (TEM) image of the semiconductor memory device including nanodots formed by the fabrication processes as above. The specimen employed in example embodiments may be prepared by depositing SiO₂ as a tunneling layer at a thickness of about 4 nm on a Si substrate, forming SiO₂ as an insulating layer at a thickness of about 15 nm thereon, and forming an Al₂O₃ thin film as a high-k dielectric layer at a thickness of about 19 nm on the insulating layer. Referring to FIG. 5, a Ni nanodot at a diameter of about 9 nm may be formed on the tunneling layer.

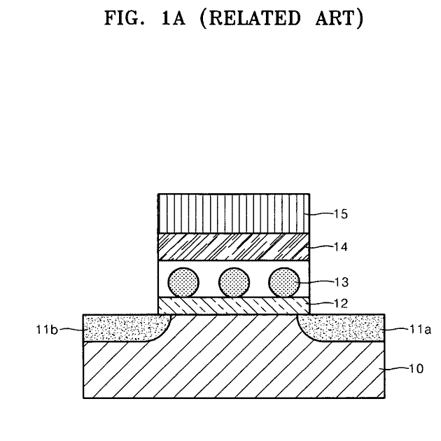

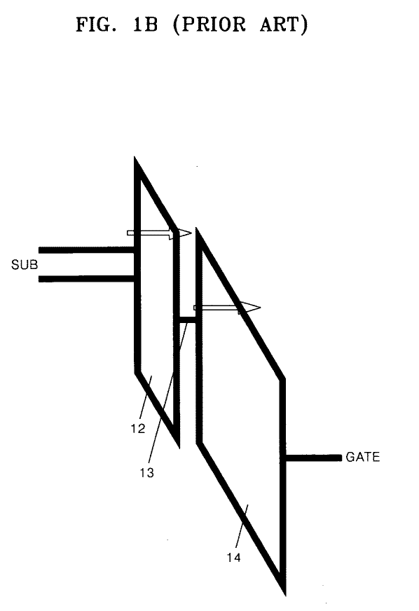

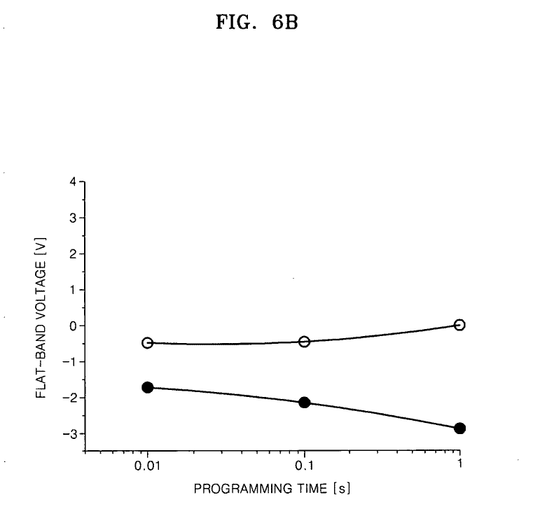

FIGS. 6A and 6B are graphs illustrating flat band voltage (V_{FB}) voltages in accordance with programming times in the conventional semiconductor memory device and the semiconductor memory device of example embodiments, respectively. FIG. 6A illustrates plots of measurement results with respect to the semiconductor memory device including the high-k dielectric layer formed by the processes in FIGS. 4A-4F, and FIG. 6B illustrates plots of measurement results with respect to the conventional semiconductor memory device having a SiO₂/Ni nanodot/SiO₂ structure without a high-k dielectric layer as shown in FIG. 1A.

Referring to FIG. 6A, an electrical field in the tunneling layer at a voltage of about 19 V may be about 10 MV/cm, and a flat band voltage shift during programming/erasing at about 10 ms may be about 3.4 V. Referring to FIG. 6B, an electrical field in the tunneling layer at a voltage of about 12 V may be about 12 MV/cm. A flat band voltage shift during programming/erasing at about 10 ms may be about 1 V. An efficiency of programming/erasing of the semiconductor memory device including the high-k dielectric layer according to example embodiments may be higher. According to example embodiments, because a high-k dielectric layer is formed on a control insulating layer of a nonvolatile memory device including nanodots, and charges injected into the nanodots through a tunneling layer flow to the control insulating layer, deterioration of a programming efficiency may be reduced or prevented. A back-tunneling phenomenon (e.g., charges flow back to the control insulating layer through a gate electrode layer) may be reduced or prevented. As a result, programming/erasing characteristics may be improved.

While example embodiments have been particularly shown and described with reference to example embodiments thereof, it will be understood by those of ordinary skill in the art that various changes in form and details may be made therein without departing from the spirit and scope of the following claims.

What is claimed is:

1. A gate structure comprising:
a tunneling layer;
a plurality of nanodots on the tunneling layer;
an insulating layer on the tunneling layer and the plurality of nanodots;
a high-k dielectric layer on the insulating layer;
a second insulating layer on the high-k dielectric layer;
a second high-k dielectric layer on the second insulating layer; and
a third insulating layer on the second high-k dielectric layer.

2. A semiconductor memory device comprising:
a semiconductor substrate;
a first impurity region and a second impurity region in the semiconductor substrate; and
the gate structure of claim 1 on the semiconductor substrate, wherein the gate structure is in contact with the first and second impurity regions.

3. The gate structure of claim 1, wherein the high-k dielectric layer includes at least one material of high-k dielectric materials selected from Si₃N₄, Al₂O₃, HfO₂, Ta₂O₅ , ZrO₂, HfSiO₄, and ZrSiO₄.

4. The gate structure of claim 1, wherein the plurality of nanodots is one of Ni, Cu, Pd, Au, Ag, Fe, Co, Mn, Cr, V, Mo, Nb and Ru.

5. The gate structure of claim 1, further comprising:
a gate electrode layer on the third insulating layer.

6. The semiconductor device of claim 5, wherein the gate electrode layer is composed of Ru, TaN metal or a silicide material.
